(19) United States
(12) Patent Application Publication
(10) Pub. No.: US 2025/0113743 A1
(43) Pub. Date: Apr. 3, 2025

(54) JOSEPHSON JUNCTION PREPARATION METHOD AND JOSEPHSON JUNCTION

(71) Applicant: YANGTZE DELTA INDUSTRIAL INNOVATION CENTER OF QUANTUM SCIENCE AND TECHNOLOGY, Suzhou (CN)

(72) Inventors: Weiwen ZHENG, Suzhou (CN); Tian LUAN, Suzhou (CN); Huide ZHOU, Suzhou (CN); Bo FAN, Suzhou (CN)

(21) Appl. No.: 18/979,702

(22) Filed: Dec. 13, 2024

Related U.S. Application Data
(63) Continuation of application No. PCT/CN2024/070280, filed on Jan. 3, 2024.

(30) Foreign Application Priority Data
Jan. 10, 2023 (CN) 202310032246.6

(51) Int. Cl. H10N 60/01; H10N 60/12

(52) U.S. Cl. CPC H10N 60/0912; H10N 60/12

(57) ABSTRACT

The present application discloses a Josephson junction preparation method and a Josephson junction, wherein a mask is provided with a first channel and a second channel, one end of the second channel coincides with the first channel, and a three-end channel is formed; a strip-shaped first superconducting layer is formed on the side, away from the evaporation source, in the first channel in the first evaporation direction; an included angle is formed between the first evaporation direction and the surface normal of the substrate, and the first evaporation direction enables the first superconducting layer to be only arranged in the first channel; a second superconducting layer is arranged in the second channel in the second evaporation direction, and forming a Josephson junction in the overlapped area of the first channel and the second channel.

### CROSS-REFERENCE TO RELATED APPLICATIONS

The present application is a continuation of International Application No. PCT/CN2024/070280, with an international filing date of Jan. 3, 2024, which is based upon and claims priority to Chinese Patent Application No. 202310032246.6, filed on Jan. 10, 2023, the entire contents of all of which are incorporated herein by reference.

### TECHNICAL FIELD

The present disclosure relates to a technical field of quantum chip, particularly to a Josephson junction preparation method and a Josephson junction.

### BACKGROUND

Josephson junction is the most important device in superconducting quantum chips. Because of its non-equidistant energy level states, the two lowest energy levels thereof can be used to form a two-level system in quantum bits. The structure of a Josephson junction is generally SIS (superconductor-insulating layer-superconductor) structure, i.e., a sandwich structure of superconducting layer-insulating layer-superconducting layer, which is usually processed and prepared by utilizing metallic Al as the source material at present. In superconducting quantum chips, the line width of a Josephson junction is mostly between 100 nm and 300 nm, which requires a high resolution precision of photoetching equipment, with EBL (electron beam lithography system) equipment as a main exposure processing method. Currently, the conventional preparation solution is to prepare a cross-shaped pattern area through photoetching; evaporate an aluminum film twice along two mutually vertical directions of a cross, respectively, and at an included angle to the horizontal plane, by utilizing the shielding effect of the photoresist; and oxidize after the first aluminum plating to form an insulating layer.

However, in the prior art, the size of Josephson junction in the current superconducting quantum chip is generally in a range of 100-300 nm, which requires a high resolution precision of photoetching equipment, with EBL equipment as a main exposure processing method, and is costly and slow, and cannot be prepared quickly in large quantities. Also, the size of the Josephson junction is determined by the line width of the photoetching, and cannot be adjusted when the line width is constant. Accordingly, how to provide a method for flexibly adjusting the area of Josephson junctions without the need for a high-resolution device is an urgent problem to be solved by those skilled in the art.

### SUMMARY

The present disclosure aims at providing a Josephson junction preparation method which can flexibly adjust the area of Josephson junctions without the need for a high-resolution device. The present disclosure further aims at providing a Josephson junction, which can flexibly adjust the area of Josephson junctions without the need for a high-resolution device.

To solve the above technical problem, the present disclosure provides a Josephson junction preparation method, comprising:
arranging a mask on a surface of a substrate; providing a mask with a first channel and a second channel, one end of the second channel coincides with the first channel, and a three-end channel is formed; an axis of the first channel intersects an axis of the second channel;
forming a strip-shaped first superconducting layer on one side, away from an evaporation source, in the first channel in a first evaporation direction; an included angle is formed between the first evaporation direction and the surface normal of the substrate, a component of the first evaporation direction in the horizontal direction forms an included angle with the axis of the second channel, such that the first superconducting layer is only arranged in the first channel;
arranging an insulating layer on the surface of the first superconducting layer; and
arranging a second superconducting layer in the second channel in a second evaporation direction, and forming a Josephson junction in an overlapped area of the first channel and the second channel; a component of the second evaporation direction in the horizontal direction is parallel to the axis of the second channel; an included angle is formed between the second evaporation direction and the surface normal of the substrate, causing the second superconducting layer to be disposed only within the second channel.

Alternatively, the axis of the first channel intersects non-perpendicularly with the axis of the second channel, and the component of the first evaporation direction in the horizontal direction is perpendicular to the axis of the first channel.

Alternatively, a first included angle is formed between the first channel and the second channel, and a second included angle is formed between the first evaporation direction and the surface normal of the substrate, satisfying:

$$L 2 / cos θ1 < H \times tan α1 < L 1 ;$$

wherein L1 is a width of the first channel, L2 is a width of the second channel, H is a thickness of the mask, θ1 is the first included angle, and α1 is the second included angle.

Alternatively, a third included angle is formed between the second evaporation direction and the surface normal of the substrate, satisfying:

$$H \times tan β 1 > L 1 / sin θ1 ;$$

wherein β1 is the third included angle.

Alternatively, the axis of the first channel intersects perpendicularly with the axis of the second channel, and the component of the first evaporation direction in the horizontal direction intersects non-perpendicularly with the axis of the first channel.

Alternatively, a fourth included angle is formed between the first channel and the first evaporation direction, and a fifth included angle is formed between the first evaporation direction and the surface normal of the substrate, satisfying:

$$L 2 < H \times tan α 2 \times sin θ 2 < L 1 ;$$

wherein L1 is a width of the first channel, L2 is the width of the second channel, H is a thickness of the mask, θ2 is the fourth included angle, and α2 is the fifth included angle.

Alternatively, the second evaporation direction forms a sixth included angle with the surface normal of the substrate, satisfying:

$$H \times tan β 2 > L 1 ;$$

wherein β2 is the sixth included angle.

Alternatively, the step of arranging a mask on a surface of a substrate comprises:
providing the mask on the surface of the substrate via photoetching equipment.

Alternatively, the step of providing the mask on the surface of the substrate via photoetching equipment comprises:
providing the mask on the surface of the substrate through an I-Line device or a laser direct writer.

The present disclosure further provides a Josephson junction, being a Josephson junction prepared by the Josephson junction preparation method according to any one of the above steps.

The present disclosure further provides a superconducting quantum chip, comprising a Josephson junction prepared by the Josephson junction preparation method according to any one of the above steps.

The present disclosure further provides a superconducting quantum computer, comprising the superconducting quantum chip.

The Josephson junction preparation method provided by the present disclosure comprises: arranging a mask on a surface of a substrate; providing a mask with a first channel and a second channel, one end of the second channel coincides with the first channel, and a three-end channel is formed; an axis of the first channel intersects an axis of the second channel; forming a strip-shaped first superconducting layer on one side, away from an evaporation source, in the first channel in a first evaporation direction; an included angle is formed between the first evaporation direction and the surface normal of the substrate, a component of the first evaporation direction in the horizontal direction forms an included angle with the axis of the second channel, such that the first superconducting layer is only arranged in the first channel; arranging an insulating layer on the surface of the first superconducting layer; and arranging a second superconducting layer in the second channel in a second evaporation direction, and forming a Josephson junction in an overlapped area of the first channel and the second channel; a component of the second evaporation direction in the horizontal direction is parallel to the axis of the second channel; an included angle is formed between the second evaporation direction and the surface normal of the substrate, causing the second superconducting layer to be disposed only within the second channel.

The Josephson junction is only in an area where the first channel coincides with the second channel, and the area of the Josephson junction is regulated and controlled by the first evaporation direction, so that the area of the Josephson junction can be flexibly adjusted without the need for a high-resolution device.

The present disclosure further provides a Josephson junction, which can achieve the above advantageous effects, and thus will not be described in detail herein.

### BRIEF DESCRIPTION OF THE DRAWINGS

In order to more clearly explain the technical solutions in the embodiments of the present disclosure or the prior art, drawings required in the embodiments or the prior art will be briefly described below. Obviously, the drawings in the following description are some embodiments of the present disclosure. For those skilled in the art, other drawings may be obtained from these drawings without any creative effort.

FIG. 1 is a process flow diagram of a Josephson junction preparation method according to an embodiment of the present disclosure;

FIGS. 2 to 4 are process flow diagrams of a first specific Josephson junction preparation method according to an embodiment of the present disclosure;

FIGS. 5 to 7 are process flow diagrams of a second specific Josephson junction preparation method according to an embodiment of the present disclosure.

In the figures: 1. mask, 2. the first channel, 3. the second channel, 4. the first superconducting layer, 5. the second superconducting layer.

### DETAILED DESCRIPTION OF THE EMBODIMENTS

The core of the present disclosure is to provide a Josephson junction preparation method. In the prior art, the preparation of Josephson junction requires a high resolution precision of photoetching equipment, with EBL equipment as a main exposure processing method, which is costly and slow, and cannot be prepared quickly in large quantities. Also, the size of the Josephson junction is determined by the line width of the photoetching, and cannot be adjusted when the line width is constant.

However, the Josephson junction preparation method provided by the present disclosure comprises: arranging a mask on a surface of a substrate; providing a mask with a first channel and a second channel, one end of the second channel coincides with the first channel, and a three-end channel is formed; an axis of the first channel intersects an axis of the second channel; forming a strip-shaped first superconducting layer on one side, away from an evaporation source, in the first channel in a first evaporation direction; an included angle is formed between the first evaporation direction and the surface normal of the substrate, a component of the first evaporation direction in the horizontal direction forms an included angle with the axis of the second channel, such that the first superconducting layer is only arranged in the first channel; arranging an insulating layer on the surface of the first superconducting layer; and arranging a second superconducting layer in the second channel in a second evaporation direction, and forming a Josephson junction in an overlapped area of the first channel and the second channel; a component of the second evaporation direction in the horizontal direction is parallel to the axis of the second channel; an included angle is formed between the second evaporation direction and the surface normal of the substrate, causing the second superconducting layer to be disposed only within the second channel.

The Josephson junction is only in an area where the first channel coincides with the second channel, and the area of the Josephson junction is regulated and controlled by the first evaporation direction, so that the area of the Josephson junction can be flexibly adjusted without the need for a high-resolution device.

In order to enable those skilled in the art to better understand the aspects of the present disclosure, the present disclosure will now be described in further detail with reference to the accompanying drawings and detailed description. Obviously, the described embodiments are part of, but not all of, the embodiments of the present disclosure. Based on the embodiments of the present disclosure, all the other embodiments obtained by those skilled in the art without paying any creative work fall within the protection scope of the present disclosure.

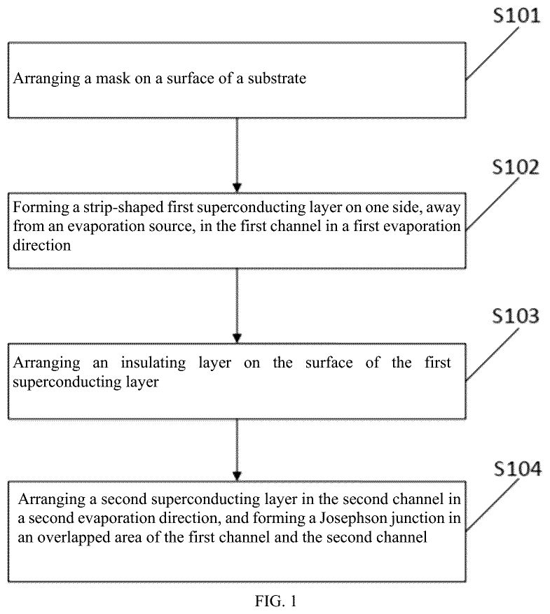

With reference to FIG. 1, FIG. 1 is a process flow diagram of a Josephson junction preparation method according to an embodiment of the present disclosure.

Referring to FIG. 1, in an embodiment of the present disclosure, a Josephson junction preparation method comprises:

S101: arranging a mask on a surface of a substrate.

In the embodiment of the present disclosure, a mask 1 is provided with a first channel 2 and a second channel 3, one end of the second channel 3 coincides with the first channel 2, and a three-end channel is formed; and an axis of the first channel 2 intersects an axis of the second channel 3.

The substrate can be a high-resistance silicon substrate or a sapphire substrate, serving as a carrier structure of a superconducting quantum chip. In this step, a mask 1 having a certain thickness is provided on the surface of the substrate, and a Josephson junction is provided in the subsequent steps based on the mask 1 having a certain thickness.

The mask 1 is provided with a first channel 2 and a second channel 3, and the first channel 2 and the second channel 3 are generally linear and have an axis, wherein the axis of the first channel 2 intersects the axis of the second channel 3, i.e., the first channel 2 partially coincides with the second channel 3; specifically, the end of the second channel 3 overlaps the middle part of the first channel 2, thereby forming a three-end channel.

Specifically, this step may comprise providing the mask 1 on the surface of the substrate via photoetching equipment. That is, the mask 1 may be made of a photoresist, and the first channel 2 and the second channel 3 are formed by photoetching equipment. The photoresist is not limited to a specific type, and may be a single-layer or a multilayer photoresist. Further, the step may comprise providing the mask 1 on the surface of the substrate through an I-Line device or a laser direct writer. I-Line device and a laser direct writer belong to photoetching equipment with lower line width resolution. Since the area of the Josephson junction can be adjusted based on the adjustment of the evaporation angle in the embodiment of the present disclosure, the above channel can be arranged using photoetching equipment with lower line width resolution in this step.

S102: forming a strip-shaped first superconducting layer on one side, away from an evaporation source, in the first channel in a first evaporation direction.

In the embodiment of the present disclosure, an included angle is formed between the first evaporation direction and the surface normal of the substrate, a component of the first evaporation direction in the horizontal direction forms an included angle with the axis of the second channel 3, such that the first superconducting layer 4 is only arranged in the first channel 2.

The adjustment of the evaporation direction can be realized by rotating the sample or by other means, and the first evaporation direction is specifically a direction having an inclination angle in three-dimensional directions with respect to the mask 1. That is, the first evaporation direction has one component in the vertical direction with respect to the mask 1, and the first evaporation direction also has one component in the horizontal direction with respect to the mask 1.

The first channel 2 has a side close to the evaporation source and a side away from the evaporation source relative to the evaporation source of the first evaporation. Specifically, the first evaporation direction has a component in the vertical direction with respect to the mask 1, that is, an included angle is formed between the first evaporation direction and the surface normal of the substrate, so that the strip-shaped first superconducting layer 4 can be formed on the side away from the evaporation source in the first channel 2 during the evaporation process. In the embodiment of the present disclosure, the area of the Josephson junction can be adjusted by adjusting the component of the first evaporation direction in the vertical direction with respect to the mask 1, and on the side of the first channel 2 that is close to the evaporation source, a superconducting material is not vaporized by the blockage of the mask 1 on that side due to the side wall of the first channel 2, and a first superconducting layer 4 is formed.

The first evaporation direction has a component in the horizontal direction with respect to the mask 1, such that the component of the first evaporation direction in the horizontal direction forms an included angle with the axis of the second channel 3, and said included angle enables the first superconducting layer 4 to be only disposed in the first channel 2 instead of in the second channel 3. That is, the component of the first evaporation direction in the horizontal direction with respect to the mask 1 can prevent the evaporated material from falling into the second channel 3 under the obstruction of the mask 1 corresponding to the side wall of the second channel 3, but enables it to only fall into the first channel 2, thereby ensuring the control of the Josephson junction morphology.

S103: arranging an insulating layer on the surface of the first superconducting layer.

In this step, the first superconducting layer 4 may be specifically oxidized to provide an oxide layer as an insulating layer on the surface of the first superconducting layer 4. Certainly, other materials may be provided as an insulating layer on the surface of the first superconducting layer 4 by other processes, which will not be described herein.

S104: arranging a second superconducting layer in the second channel in a second evaporation direction, and forming a Josephson junction in an overlapped area of the first channel and the second channel.

In the embodiment of the present disclosure, a component of the second evaporation direction in the horizontal direction is parallel to the axis of the second channel 3; an included angle is formed between the second evaporation direction and the surface normal of the substrate, causing the second superconducting layer 5 to be disposed only within the second channel 3.

The second evaporation direction is specifically a direction having an inclination angle in three-dimensional directions with respect to the mask 1. That is, the second evaporation direction has one component in the vertical direction with respect to the mask 1, and the second evaporation direction also has one component in the horizontal direction with respect to the mask 1.

During the second evaporation, the component of the second evaporation direction in the horizontal plane needs to be parallel to the axis of the second channel 3, that is, the second evaporation needs to be performed along the second channel 3, so that the second superconducting layer 5 is provided in the second channel 3. The above second evaporation direction has a component in a vertical direction with respect to the mask 1, i.e., the second evaporation direction forms an included angle with the normal surface of the substrate, and said included angle enables the second superconducting layer 5 to be disposed only within the second channel 3 instead of in the first channel 2. That is, the component of the second evaporation direction in the vertical direction with respect to the mask 1 can prevent the deposited material from falling into the first channel 2 under the obstruction of the mask 1 corresponding to the side wall of the first channel 2, but enables it to only fall into the second channel 3, ensuring the control of the Josephson junction morphology.

An area where the first superconducting layer 4, the insulating layer, and the second superconducting layer 5 overlap forms a Josephson junction, and then is disposed only in the first channel 2 in the first evaporation, and only in the second channel 3 in the second evaporation. Therefore, the Josephson junction is formed only in the area where the first channel 2 overlaps the second channel 3, and the width of the first superconducting layer 4 is controlled by the first evaporation direction. Accordingly, the morphology of the Josephson junction can be controlled by controlling the first evaporation direction.

After this step, it is usually necessary to strip the above sample, i.e., to remove the above mask 1 to obtain the desired Josephson junction.

In the Josephson junction preparation method provided by the embodiments of the present disclosure, the Josephson junction is only in the area where the first channel 2 coincides with the second channel 3, and the area of the Josephson junction is regulated and controlled by the first evaporation direction, so that the area of the Josephson junction can be flexibly adjusted without the need for a high-resolution device.

The specific contents of a Josephson junction preparation method provided by the present disclosure will be described in detail in the following embodiments of the present disclosure.

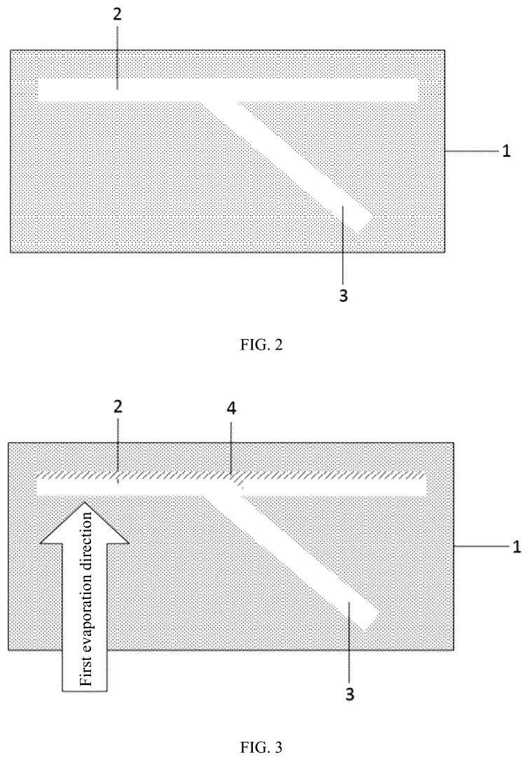

With reference to FIGS. 2 to 4, FIGS. 2 to 4 are process flow diagrams of a first specific Josephson junction preparation method according to an embodiment of the present disclosure.

In an embodiment of the present disclosure, a Josephson junction preparation method comprises:

S201: arranging a mask on a surface of a substrate.

Referring to FIG. 2, in an embodiment of the present disclosure, the axis of the first channel 2 intersects non-perpendicularly with the axis of the second channel 3, and the component of the first evaporation direction in the horizontal direction is perpendicular to the axis of the first channel 2.

That is, in the mask 1, the first channel 2 is not perpendicular to the second channel 3, but is disposed at a non-90 o included angle. At this time, the component of the first evaporation direction in the horizontal direction is perpendicular to the axis of the first channel 2, and the component of the first evaporation direction in the horizontal direction is disposed at an angle to the axis of the second channel 3.

S202: forming a strip-shaped first superconducting layer on one side, away from an evaporation source, in the first channel in a first evaporation direction.

Referring to FIG. 3, further, a first included angle is formed between the first channel 2 and the second channel 3, and a second included angle is formed between the first evaporation direction and the surface normal of the substrate, satisfying:

$$L 2 / cos θ1 < H \times tan α 1 < L 1 ;$$

wherein L1 is a width of the first channel 2, L2 is a width of the second channel 3, H is a thickness of the mask 1, θ1 is the first included angle, and α1 is the second included angle.

At this time, when the first evaporation direction conforms to the above range, it can be realized that only a strip-shaped first superconducting layer 4 is vaporized in the first channel 2 without vaporizing the superconducting material in the second channel 3. The width of the first superconducting layer 4 is smaller than the width of the first channel 2. At this time, since the intersection of the first channel 2 and the second channel 3 has a larger width, a triangular superconducting material that does not affect the Josephson junction morphology is formed in the first channel 2. The morphology of the Josephson junction will not be affected because this triangular area will avoid the second channel 3.

S203: arranging an insulating layer on the surface of the first superconducting layer.

This step has been described in S103 in the above embodiment of the present disclosure, and will not be repeated herein.

S204: arranging a second superconducting layer in the second channel in a second evaporation direction, and forming a Josephson junction in an overlapped area of the first channel and the second channel.

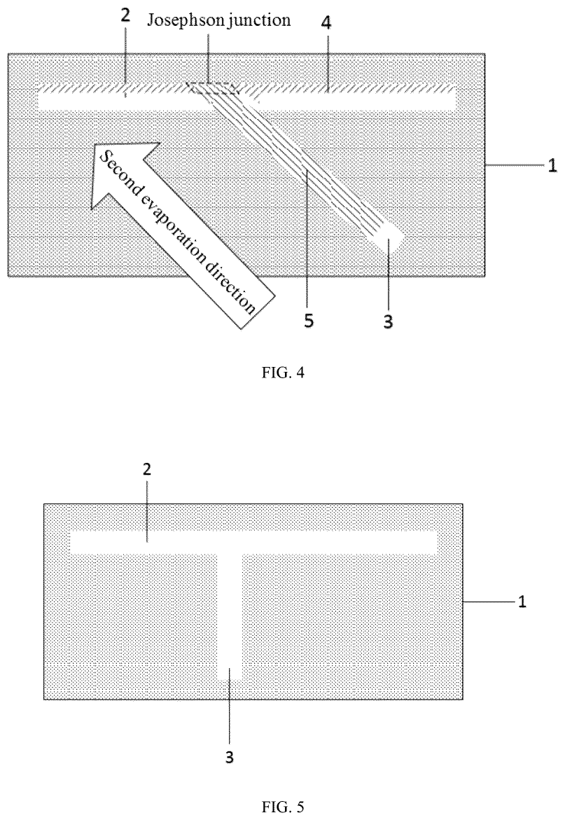

Referring to FIG. 4, further, a third included angle is formed between the second evaporation direction and the surface normal of the substrate, satisfying:

$$H \times tan β 1 > L 1 / sin θ1 ;$$

wherein β1 is the third included angle.

At this time, when the second evaporation direction conforms to the above range, it can be realized that only a strip-shaped second superconducting layer 5 is vaporized in the second channel 3 without vaporizing the superconducting material in the first channel 2. The width of the second superconducting layer 5 is equal to the width of the second channel 3. However, a Josephson junction is formed in the area where the first superconducting layer 4 and the second superconducting layer 5 overlap.

Specifically, in order to prepare a Josephson junction with an area equivalent to 200 nm×200 nm in the embodiment of the present disclosure, the specific parameters are listed as follows: H=2000 nm, L1=1000 nm, L2=400 nm, θ1=60°, α1=24.5°, β1=45°.

In the Josephson junction preparation method provided by the embodiments of the present disclosure, the Josephson junction is only in the area where the first channel 2 coincides with the second channel 3, and the area of the Josephson junction is regulated and controlled by the first evaporation direction, so that the area of the Josephson junction can be flexibly adjusted without the need for a high-resolution device.

The specific contents of a Josephson junction preparation method provided by the present disclosure will be described in detail in the following embodiments of the present disclosure.

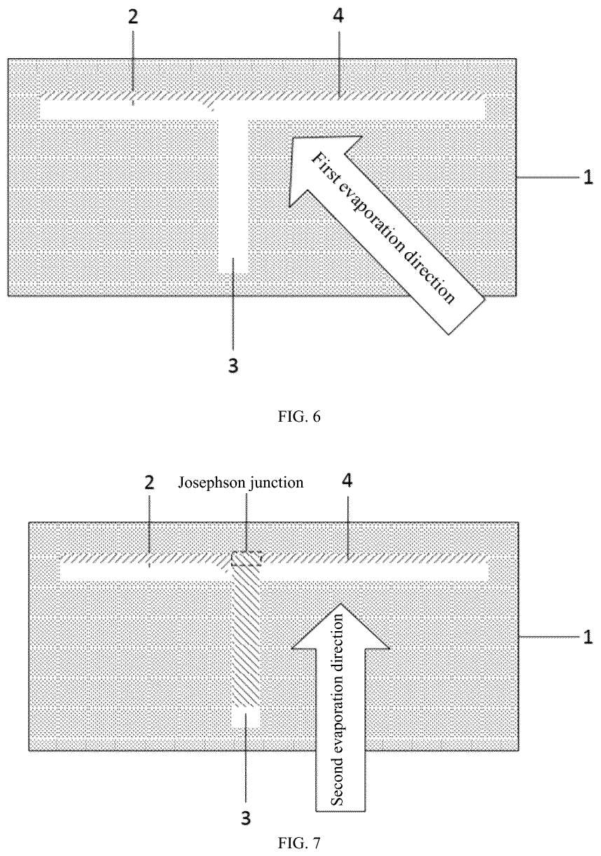

With reference to FIGS. 5 to 7, FIGS. 5 to 7 are process flow diagrams of a second specific Josephson junction preparation method according to an embodiment of the present disclosure.

In an embodiment of the present disclosure, a Josephson junction preparation method comprises:

S301: arranging a mask on a surface of a substrate.

Referring to FIG. 5, the axis of the first channel 2 intersects perpendicularly with the axis of the second channel 3, and the component of the first evaporation direction in the horizontal direction intersects non-perpendicularly with the axis of the first channel 2.

That is, in the mask 1, the first channel 2 is perpendicular to the second channel 3, forming a 90 o included angle. At this time, the component of the first evaporation direction in the horizontal direction is perpendicular to the axis of the first channel 2, and at the same time intersects non-perpendicularly with the axis of the second channel 3, forming an angle.

S302: forming a strip-shaped first superconducting layer on one side, away from an evaporation source, in the first channel in a first evaporation direction.

Further, a fourth included angle is formed between the first channel 2 and the first evaporation direction, and a fifth included angle is formed between the first evaporation direction and the surface normal of the substrate, satisfying:

$$L 2 < H \times tan α 2 \times sin θ 2 < L 1 ;$$

wherein L1 is a width of the first channel 2, L2 is the width of the second channel 3, H is a thickness of the mask 1, θ2 is the fourth included angle, and α2 is the fifth included angle.

At this time, when the first evaporation direction conforms to the above range, it can be realized that only a strip-shaped first superconducting layer 4 is vaporized in the first channel 2 without vaporizing the superconducting material in the second channel 3. The width of the first superconducting layer 4 is smaller than the width of the first channel 2. At this time, since the intersection of the first channel 2 and the second channel 3 has a larger width, a triangular superconducting material that does not affect the Josephson junction morphology is formed in the first channel 2. The morphology of the Josephson junction will not be affected because this triangular area will avoid the second channel 3.

S303: arranging an insulating layer on the surface of the first superconducting layer.

This step has been described in S103 in the above embodiment of the present disclosure, and will not be repeated herein.

S304: arranging a second superconducting layer in the second channel in a second evaporation direction, and forming a Josephson junction in an overlapped area of the first channel and the second channel.

Further, the second evaporation direction forms a sixth included angle with the surface normal of the substrate, satisfying:

$$H \times tan β 2 > L 1 ;$$

wherein β2 is the sixth included angle.

At this time, when the second evaporation direction conforms to the above range, it can be realized that only a strip-shaped second superconducting layer 5 is vaporized in the second channel 3 without vaporizing the superconducting material in the first channel 2. The width of the second superconducting layer 5 is equal to the width of the second channel 3. However, a Josephson junction is formed in the area where the first superconducting layer 4 and the second superconducting layer 5 overlap.

In order to prepare Josephson junction with an area equivalent to 200 nm×200 nm, the specific parameters are listed as follows: H=2000 nm, L1=1000 nm, L2=400 nm, θ2=30°, α2=42°, β2=45°.

In the Josephson junction preparation method provided by the embodiments of the present disclosure, the Josephson junction is only in the area where the first channel 2 coincides with the second channel 3, and the area of the Josephson junction is regulated and controlled by the first evaporation direction, so that the area of the Josephson junction can be flexibly adjusted without the need for a high-resolution device.

The present disclosure also provides a Josephson junction, being a Josephson junction prepared by the Josephson junction preparation method according to any one of the embodiments of the present disclosure.

In the Josephson junction preparation method provided by the embodiments of the present disclosure, the Josephson junction is only in the area where the first channel 2 coincides with the second channel 3, and the area of the Josephson junction is regulated and controlled by the first evaporation direction, so that the area of the Josephson junction can be flexibly adjusted without the need for a high-resolution device. Accordingly, the Josephson junction provided by the embodiments of the present disclosure can flexibly control the area of the Josephson junction. The specific structure and the preparation process of the Josephson junction provided by the present disclosure have been described in detail in the above embodiments of the present disclosure, and will not be described in detail herein.

The present disclosure further provides a superconducting quantum chip, comprising a Josephson junction prepared by the Josephson junction preparation method according to any one of the embodiments of the present disclosure.

The Josephson junction preparation method provided by the embodiments of the present disclosure can regulate and control the area of the Josephson junction by adjusting the first evaporation direction, so that the area of the Josephson junction can be flexibly adjusted without the need for a high-resolution device. Therefore, in the embodiment of the present disclosure, a superconducting quantum chip has a lower manufacturing cost. The specific structure and the preparation process of the Josephson junction in the superconducting quantum chip provided by the present disclosure have been described in detail in the above embodiments of the present disclosure, and will not be described in detail herein. Other structures of the superconducting quantum chip can be referenced from the prior art and will not be specifically limited, either.

The present disclosure further provides a superconducting quantum computer, comprising the superconducting quantum chip according to any one of the embodiments of the present disclosure.

The application of superconducting quantum Josephson junction preparation method in the superconducting quantum chip provided by the embodiments of the present disclosure can flexibly adjust the area of the Josephson junction without the need for a high-resolution device. Therefore, a superconducting quantum provided in the embodiment of the present disclosure computer has a lower manufacturing cost. The specific structure and the preparation process of the Josephson junction in the superconducting quantum computer provided by the embodiment of present disclosure have been described in detail in the above embodiments of the present disclosure, and will not be described in detail herein. Other structures of the superconducting quantum computer can be referenced from the prior art and will not be specifically limited, either.

Each embodiment in the specification is described in a progressive manner, each embodiment focuses on the differences from other embodiments, and the same or similar parts among the embodiments can be referenced to each other.

Those skilled in the art may further realize that the units and algorithmic steps of the examples described in conjunction with the embodiments disclosed herein can be implemented in electronic hardware, computer software, or a combination thereof. To clearly illustrate the interchangeability of hardware and software, the components and steps of the examples have been described generally in terms of function in the above description. Whether these functions are performed in hardware or software depends on the particular application and design constraints of the technical solution. Those skilled in the art may use different methods to implement the described functions for each particular application, but such implementations should not be considered as going beyond the scope of the present disclosure.

The steps of the methods or algorithms described in conjunction with the embodiments disclosed herein may be implemented directly with hardware, a software module executed by a processor, or a combination thereof. A software module may be placed in random access memory (RAM), memory, read-only memory (ROM), electrically programmable ROM, electrically erasable programmable ROM, a register, a hard disk, a removable diskette, a CD-ROM, or any other form of storage medium known in the art.

Finally, it should also be noted that relationship terms such as first and second, etc. are used herein only to distinguish one entity or operation from another without necessarily requiring or implying any such actual relationship or order between those entities or operations. Moreover, the terms “comprise”, “include” or any other variation thereof, are intended to cover a non-exclusive inclusion, such that a process, a method, an article, or an apparatus comprising a list of elements includes not only those elements, but also other elements not explicitly listed or may include elements inherent to the process, method, article, or apparatus. Without further limitation, an element defined by the statement of “comprising a . . . ” does not exclude the further presence of additionally identical elements in a process, a method, an article or an apparatus comprising said element.

A Josephson junction preparation method and a Josephson junction are described in detail in the present disclosure. Specific examples are used herein to illustrate the principles and embodiments of the present disclosure, and the above description of the examples is merely intended to aid in the understanding of the methods of the present disclosure and the core concepts thereof. It should be noted that those skilled in the art can make several modifications and variations to the present disclosure without departing from the principles of the present disclosure, and these modifications and variations also fall within the protection scope of the claims of the present disclosure.

What is claimed is:

1. A Josephson junction preparation method, comprising:
arranging a mask on a surface of a substrate; providing a mask with a first channel and a second channel, one end of the second channel coincides with the first channel, and a three-end channel is formed; an axis of the first channel intersects an axis of the second channel;
forming a strip-shaped first superconducting layer on one side, away from an evaporation source, in the first channel in a first evaporation direction; an included angle is formed between the first evaporation direction and the surface normal of the substrate, a component of the first evaporation direction in the horizontal direction forms an included angle with the axis of the second channel, such that the first evaporation direction enables the first superconducting layer to be only arranged in the first channel;
arranging an insulating layer on the surface of the first superconducting layer; and
arranging a second superconducting layer in the second channel in a second evaporation direction, and forming a Josephson junction in an overlapped area of the first channel and the second channel; a component of the second evaporation direction in the horizontal direction is parallel to the axis of the second channel; an included angle is formed between the second evaporation direction and the surface normal of the substrate, causing the second superconducting layer to be disposed only within the second channel.

2. The method of claim 1, wherein the axis of the first channel intersects non-perpendicularly with the axis of the second channel, and the component of the first evaporation direction in the horizontal direction is perpendicular to the axis of the first channel.

3. The method of claim 2, wherein a first included angle is formed between the first channel and the second channel, and a second included angle is formed between the first evaporation direction and the surface normal of the substrate, satisfying:
$$L 2 / cos θ1 < H \times tan α 1 < L 1 ;$$
wherein L1 is a width of the first channel, L2 is a width of the second channel, H is a thickness of the mask, θ1 is the first included angle, and α1 is the second included angle.

4. The method of claim 3, wherein a third included angle is formed between the second evaporation direction and the surface normal of the substrate, satisfying:
$$H \times tan {β}_{1} > L 1 / sin {θ}_{1} ;$$
wherein β₁ is the third included angle.

5. The method of claim 1, wherein the axis of the first channel intersects perpendicularly with the axis of the second channel, and the component of the first evaporation direction in the horizontal direction intersects non-perpendicularly with the axis of the first channel.

6. The method of claim 5, wherein a fourth included angle is formed between the first channel and the first evaporation direction, and a fifth included angle is formed between the first evaporation direction and the surface normal of the substrate, satisfying:
$$L 2 < H \times tan {α}_{2} \times sin {θ}_{2} < L 1$$
wherein L1 is a width of the first channel, L2 is the width of the second channel, H is a thickness of the mask, θ₂ is the fourth included angle, and α₂ is the fifth included angle.

7. The method of claim 6, wherein the second evaporation direction forms a sixth included angle with the surface normal of the substrate, satisfying:
$$H \times tan {β}_{2} > L 1 ;$$
wherein β₂ is the sixth included angle.

8. The method of claim 1, wherein arranging a mask on a surface of a substrate comprises:
providing the mask on the surface of the substrate via photoetching equipment.

9. The method of claim 8, wherein providing the mask on the surface of the substrate via photoetching equipment comprises:
providing the mask on the surface of the substrate through an I-Line device or a laser direct writer.

10. A Josephson junction, prepared by the Josephson junction preparation method of claim 1.

11. A superconducting quantum chip, comprising a Josephson junction prepared by the Josephson junction preparation method of claim 1.
